(19) United States
(12) Patent Application Publication
(10) Pub. No.: US 2012/0097441 A1
(43) Pub. Date: Apr. 26, 2012

(54) ELECTRONIC ELEMENT AND METHOD FOR ASSEMBLING THE SAME TO CIRCUIT BOARD

(75) Inventor: Zhi-Zhong Zhou, Keelung (TW)

(73) Assignee: LOTES CO., LTD, Keelung (TW)

(21) Appl. No.: 13/035,101

(22) Filed: Feb. 25, 2011

(30) Foreign Application Priority Data
Oct. 22, 2010 (CN) 201010521877.7

(51) Int. Cl. H05K 1/18; B23K 1/00; B23K 31/02

(52) U.S. Cl. 174/260; 228/180.1

(57) ABSTRACT

An electronic element is used for being soldered to a top surface and a bottom surface of a circuit board with solder pastes, and includes: a main body, including an insulating body and multiple terminals fixed to the insulating body, in which each of the terminals has a soldering portion, the soldering portions are arranged in two rows for being soldered respectively to the top surface and the bottom surface of the circuit board, and a distance between the two rows of the soldering portions is greater than or equal to a distance between outermost sides of the solder pastes on the top surface and the bottom surface of the circuit board; and a pressing member, located at an outer side of one row of the soldering portions, movably connected to the main body, and finally fixed to the main body. A method for assembling the electronic element to a circuit board is further provided.

### CROSS-REFERENCE TO RELATED PATENT APPLICATION

This non-provisional application claims benefits and priority under 35 U.S.C. §119(a) on Chinese Patent Application No. 201010521877.7 filed in The People's Republic of China on Oct. 22, 2010, which is incorporated herein by reference in its entirety.

### FIELD OF INVENTION

The present invention relates to an electronic element and a method for assembling the same to a circuit board, and more particularly to an electronic element for being soldered to a top surface and a bottom surface of a circuit board with solder pastes on the circuit board and a method for assembling the same to a circuit board.

### BACKGROUND OF THE INVENTION

Currently, an electronic product generally includes a circuit board, on which multiple electronic elements, such as electrical connectors and chips, are mounted. The electronic elements are generally soldered on a surface of the circuit board. However, with the development of electronic products towards light and thin structures, the height of the electronic elements has become a bottleneck for light and thin structures, and thus an assembling manner (bridge-type) of disposing a part of the electronic elements at an edge of the circuit board and bridging and soldering two rows of terminals on a top surface and a bottom surface of the circuit board respectively is developed accordingly.

However, the common bridge-type assembling manner has a severe disadvantage that when the circuit board is inserted, the terminal on the electronic element pushes a solder paste on the circuit board, such that the solder paste is scratched off, thus causing poor soldering, or the adjacent solder pastes are contacted with each other, thus causing short circuit.

Therefore, a heretofore unaddressed need exists in the art to address the aforementioned deficiencies and inadequacies.

### SUMMARY OF THE INVENTION

In one aspect, the present invention is directed to an electronic element that does not push any solder paste and a method for assembling the same to a circuit board.

In one embodiment, the present invention adopts the following inventive measures and provides an electronic element that is soldered to a top surface and a bottom surface of a circuit board by utilizing solder pastes on the circuit board. The electronic element comprises: a main body, including an insulating body and multiple terminals fixed to the insulating body, in which each of the terminals has a soldering portion, the soldering portions are arranged in two rows for being soldered respectively to the top surface and the bottom surface of the circuit board, and a distance between the two rows of the soldering portions is greater than or equal to a distance between outermost sides of the solder pastes on the top surface and the bottom surface of the circuit board; and a pressing member, located at an outer side of one row of the soldering portions, movably connected to the main body, and finally fixed to the main body, in which during movement to a final fixed state, the pressing member presses the corresponding terminals, such that the distance between the two rows of the soldering portions is smaller than the distance between the outermost sides of the solder pastes on the top surface and the bottom surface of the circuit board.

The method for assembling an electronic element to a circuit board of the present invention adopts the following technical solution.

An electronic element is provided, in which the electronic element includes a main body and a pressing member, the main body includes an insulating body and multiple terminals fixed to the insulating body, each of the terminals has a soldering portion, the soldering portions are arranged in two rows for being soldered respectively to a top surface and a bottom surface of the circuit board, a distance between the two rows of the soldering portions is greater than or equal to a distance between outermost sides of solder pastes on the top surface and the bottom surface of the circuit board, the pressing member is located at an outer side of one row of the soldering portions and movably connected to the main body, and has an initial open state and a final fixed state, and at this time, the pressing member is in the initial open state.

A circuit board is provided, in which multiple solder pastes are disposed on a top surface and a bottom surface of the circuit board corresponding to the soldering portions.

The circuit board is inserted between the two rows of the soldering portions such that a gap exists between the soldering portions and the corresponding solder pastes after insertion.

The pressing member is operated to the final fixed state, during which the pressing member presses the corresponding terminals, such that the soldering portions are all contacted with the corresponding solder pastes.

The soldering portions are soldered to the circuit board respectively with the solder pastes by heating.

As compared with the prior art, according to the electronic element and the method for assembling the same to a circuit board of the present invention, the terminals are pressed by the pressing member, such that the soldering portions are contacted with the corresponding solder pastes from the outer side without pushing the solder pastes, thereby avoiding the occurrence of poor soldering and short circuit.

These and other aspects of the present invention will become apparent from the following description of the preferred embodiment taken in conjunction with the following drawings and their captions, although variations and modifications therein may be affected without departing from the spirit and scope of the novel concepts of the disclosure.

### BRIEF DESCRIPTION OF THE DRAWINGS

The drawings described below are for illustration purposes only. The drawings are not intended to limit the scope of the present teachings in any way.

FIG. 1 is a three-dimensional exploded view of an electronic element and a circuit board according to an embodiment of the present invention;

FIG. 2 is a three-dimensional assembled view of the electronic element and the circuit board as shown in FIG. 1;

FIG. 3 is a three-dimensional assembled view of the electronic element and the circuit board as shown in FIG. 1 from another angle of view;

FIG. 4 is a sectional view of the electronic element as shown in FIG. 1 (in which a pressing member is in an initial open state);

FIG. 5 is a sectional view of the electronic element as shown in FIG. 1 inserted into the circuit board before pressing; and

FIG. 6 is a sectional view of the electronic element after pressing and the circuit board as shown in FIG. 1.

### DETAILED DESCRIPTION OF THE INVENTION

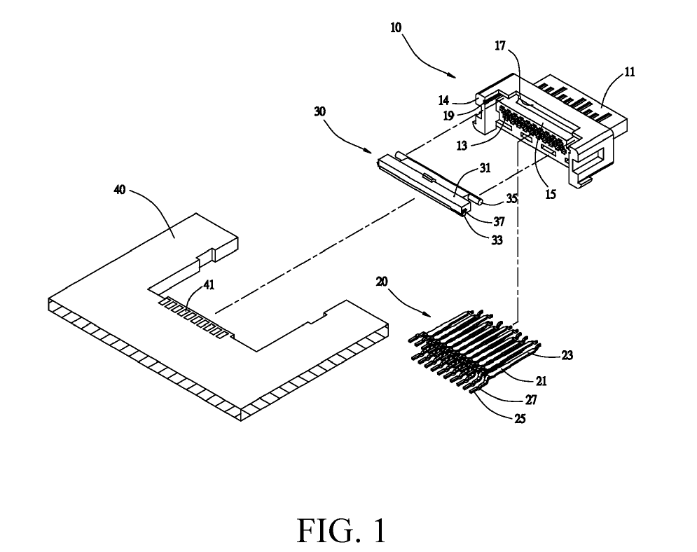

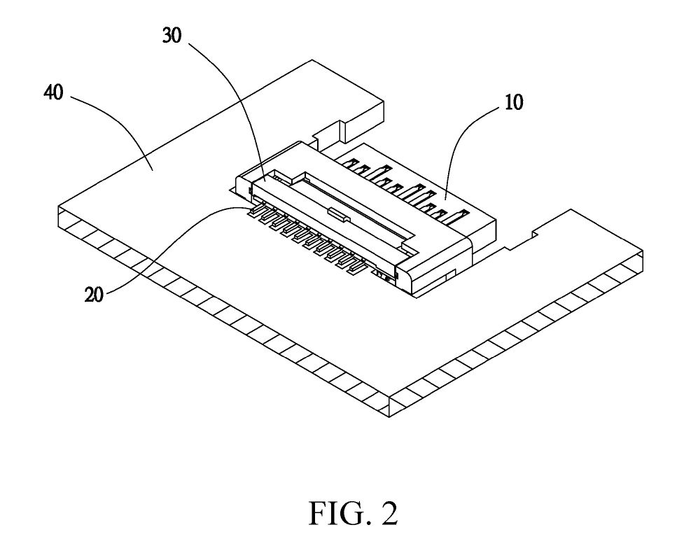

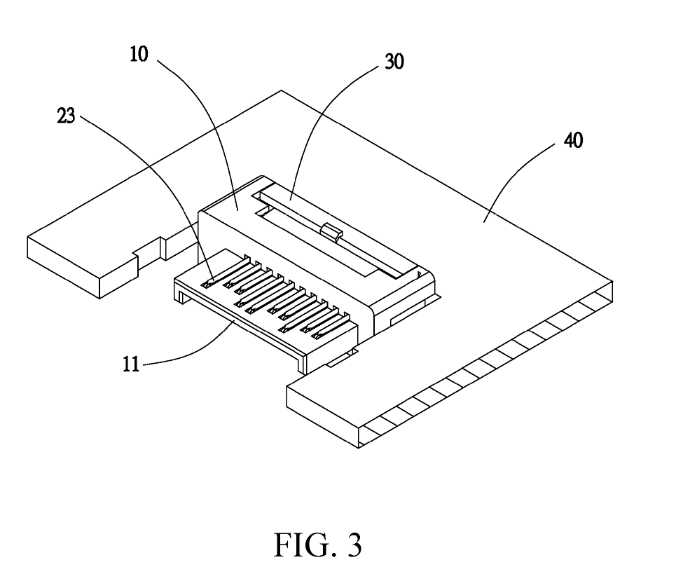

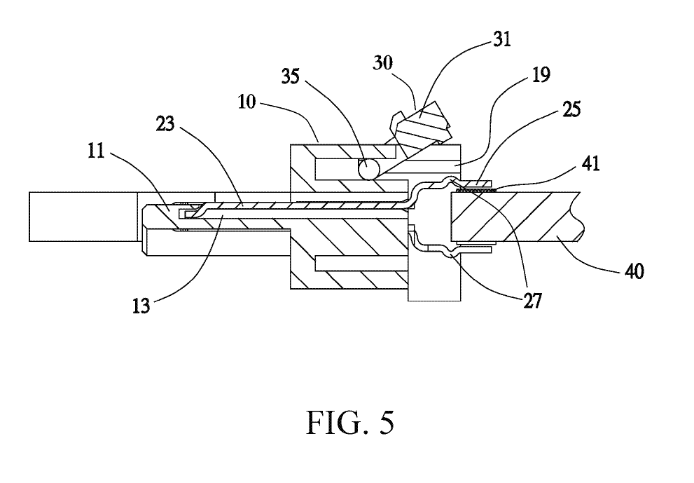

The present invention is more particularly described in the following examples that are intended as illustrative only since numerous modifications and variations therein will be apparent to those skilled in the art. Various embodiments of the invention are now described in detail. Referring to the drawings, FIGS. 1-6, like numbers, if any, indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention. Additionally, some terms used in this specification are more specifically defined below.

### DEFINITIONS

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

Unless otherwise defined, all technical and scientific terms used herein have the same meaning as commonly understood by one of ordinary skill in the art to which this invention pertains. In the case of conflict, the present document, including definitions will control.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, “plurality” means two or more.

As used herein, the terms “comprising,” “including,” “carrying,” “having,” “containing,” “involving,” and the like are to be understood to be open-ended, i.e., to mean including but not limited to.

A list of reference numerals with corresponding components as shown in the drawings is given below only for the purpose of a reader's convenience:
Insulating body 10
Tongue plate 11
Terminal receiving housing 13
Arm portion 14
Accommodating space 15
Rotating slot 17
Clamping slot 19
Terminal 20
Fixing portion 21
Butting portion 23
Soldering portion 25
Protruding portion 27
Pressing member 30
Base 31
Protruding rib 33
Rotating shaft 35
Clamping portion 37
Circuit board 40
Solder paste 41

To make the objectives, structures, features and effects of the present invention more comprehensible, the electronic element and the method for assembling the same to a circuit board according to the present invention are further described with reference to accompanying drawings and specific embodiments.

Referring now to FIGS. 1-3, in a preferred embodiment of the present invention, an electronic element is an electrical connector, which is used to connect an external electronic element (not shown) to a circuit board 40, and includes an insulating body 10, multiple terminals 20 fixed to the insulating body 10, and a pressing member 30 movably connected to the insulating body 10. Alternatively, the electronic element may also be of other types, such as a light emitting diode (LED) or a Bluetooth transmitter.

The pressing member 30 is not necessarily movably connected to the insulating body 10, and may also be movably connected to the terminals 20, or movably connected to both the insulating body 10 and the terminals 20, that is to say, the pressing member 30 is movably connected to a main body (not labeled) formed of the insulating body 10 and the terminals 20.

Multiple solder pastes 41 are disposed at predetermined positions on the circuit board 40, so as to provide solders for soldering the terminals 20 and the circuit board 40.

The insulating body 10 is substantially of a cuboidal shape, and is provided with a tongue plate 11 extending forwards at a front part thereof, and multiple terminal receiving housings 13 extending from back to front and into the tongue plate 11, and two arm portions 14 extending backwards at two sides of a rear part thereof, in which an accommodating space 15 for accommodating the pressing member 30 is formed between the two arm portions 14. At an inner side of each of the arm portions 14, a clamping slot 19 extending from back to front is disposed. At an inner side of the accommodating space 15, a rotating slot 17 is disposed, which is substantially located at an upper part of the insulating body 10, and above the terminals 20, and is substantially of a semi-cylindrical shape.

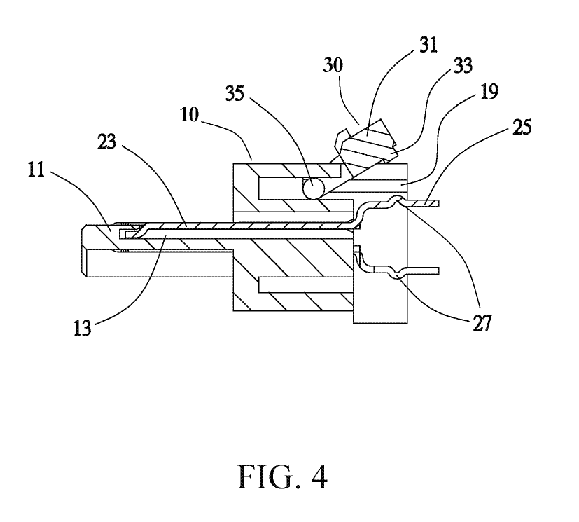

Each of the terminals 20 includes a fixing portion 21 fixed to the insulating body 10, a butting portion 23 extending forwards from the fixing portion 21 to electrically connect the external electronic element, and a soldering portion 25 extending backwards from the fixing portion 21 and located at a rear end of the fixing portion 21. Each of the butting portions 23 is received in the tongue plate 11, and at least partially exposed outside the tongue plate 11. The soldering portions 25 are used for being soldered to the circuit board 40. A protruding portion 27 is formed between the fixing portion 21 and the soldering portion 25 of each of the terminals 20 by bending, and used as a projecting portion pressed by the pressing member 30 (alternatively, the protruding portion may also be of other shapes, or formed in other manners, or even not provided). The soldering portions 25 of the terminals 20 are arranged in two rows for being soldered respectively to a top surface and a bottom surface of the circuit board 40. A distance between the two rows of the soldering portions 25 is greater than or equal to a distance between the outermost sides of the solder pastes 41 on the top surface and the bottom surface of the circuit board 40 (as shown in FIG. 4).

The pressing member 30 includes a base 31 and a protruding rib 33 extending from the base 31 towards the soldering portions 25 (downwards in this embodiment), and the protruding rib 33 forms a pressing portion for pressing the protruding portion 27 (alternatively, the pressing portion may be of other shapes). The pressing member 30 is provided with a rotating shaft 35 at an end (front end, in this embodiment) adjacent to the insulating body 10, which may be received in the rotating slot 17 to achieve the movable connection between the pressing member 30 and the main body (in this embodiment, rotatable connection is achieved with the rotating shaft 35 and the rotating slot 17, and alternatively, the movable connection may also be achieved in other manners, for example, transverse insertion). The pressing member 30 is provided with a clamping portion 37 respectively at two sides thereof corresponding to the clamping slots 19.

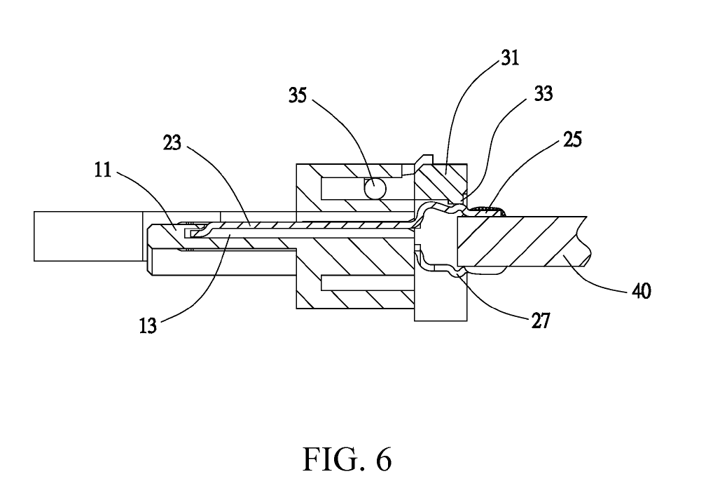

The pressing member 30 is movable between an initial open state and a final fixed state, and when being in the initial open state (as shown in FIG. 4), the pressing member 30 is at an angle relative to the insulating body 10, and is not in contact with the soldering portions 25. In a process of operating the pressing member 30 to the final fixed state, the pressing member 30 presses the corresponding protruding portions (protruding portions 27), such that the upper row of the soldering portions 25 move downwards, and thus the distance between the two rows of the soldering portion 25 is finally smaller than the distance between the outermost sides of the solder pastes 41 on the top surface and the bottom surface of the circuit board 40, and the soldering portion 25 are all contacted with the corresponding solder paste 41 (as shown in FIG. 6). When the pressing member 30 is in the final fixed state, the clamping portions 37 are clamped and fixed in the corresponding clamping slots 19, so as to maintain the pressing member 30 in this state.

As shown in FIGS. 4-6, a method for assembling the electronic element to the circuit board 40 includes the following steps.

An electronic element is provided, in which the electronic element includes a main body and a pressing member 30, the main body includes the insulating body 10 and the terminals 20 fixed to the insulating body 10, each of the terminals 20 has the soldering portion 25, and the soldering portions 25 are arranged in two rows for being soldered respectively to the top surface and the bottom surface of the circuit board 40, the distance between the two rows of the soldering portions 25 is greater than or equal to the distance between the outermost sides of the solder pastes 41 on the top surface and the bottom surface of the circuit board 40, the pressing member 30 is located at an outer side of one row of the soldering portions 25 and movably connected to the main body, and has an initial open state and a final fixed state, and at this time, the pressing member 30 is in the initial open state.

The circuit board 40 is provided, in which the solder pastes 41 are disposed on the top surface and the bottom surface of the circuit board 40 corresponding to the soldering portions 25.

The circuit board 40 is inserted between the two rows of the soldering portions 25 such that a gap exists between the soldering portions 25 and the corresponding solder pastes 41 after insertion.

The pressing member 30 is operated to the final fixed state, during which the pressing member 30 presses the corresponding terminals 20, such that the soldering portions 25 are all contacted with the corresponding solder pastes 41.

The soldering portions 25 are soldered to the circuit board 40 respectively with the solder pastes 41 by heating.

In this embodiment, the pressing member 30 includes the base 31 and the protruding rib 33 extending from the base 31 towards the soldering portions 25, and the protruding rib 33 forms the pressing portion for pressing the terminals 20. By pressing with the protruding rib 33, the position is precise, so that a good pressing effect can be ensured.

In this embodiment, the pressing member 30 is provided with the rotating shaft 35 at the end adjacent to the insulating body 10, the insulating body 10 is correspondingly provided with the rotating slot 17, and the rotating shaft 35 is received in the rotating slot 17 to achieve the movable connection between the pressing member 30 and the main body. By achieving the movable connection through rotation, the structure is simple, and the operation is easy.

In this embodiment, the pressing member 30 is provided with the clamping portion 37 respectively at two sides thereof, the insulating body 10 is correspondingly provided with the two clamping slots 19, and when the pressing member 30 is in the final fixed state, the clamping portions 37 are clamped and fixed in the corresponding clamping slots 19. In this way, a good fixing effect can be achieved, so as to avoid the rebound of the pressing member 30.

In this embodiment, each of the terminals 20 mating with the pressing member 30 is provided with the protruding portion (protruding portion 27) at the position adjacent to the soldering portion 25, and the pressing member 30 presses the terminal 20 through pressing the protruding portion. Interference with other portions of the terminal 20 can be avoided by means of the protruding portion. The protruding portion 27 formed by bending can reduce the outwards deflection of the soldering portion 25, thus improving the pressing effect.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electronic element, for being soldered to a top surface and a bottom surface of a circuit board with solder pastes on the circuit board, comprising:
a main body, comprising an insulating body and multiple terminals fixed to the insulating body, wherein each of the terminals has a soldering portion, the soldering portions are arranged in two rows for being soldered respectively to the top surface and the bottom surface of the circuit board, and a distance between the two rows of the soldering portions is greater than or equal to a distance between outermost sides of the solder pastes on the top surface and the bottom surface of the circuit board; and
a pressing member, located at an outer side of one row of the soldering portions, movably connected to the main body, and finally fixed to the main body, wherein during movement to a final fixed state, the pressing member presses the corresponding terminals, such that the distance between the two rows of the soldering portions is smaller than the distance between the outermost sides of the solder pastes on the top surface and the bottom surface of the circuit board.

2. The electronic element according to claim 1, wherein the pressing member comprises a base and a protruding rib extending from the base towards the soldering portions, and the protruding rib forms a pressing portion for pressing the terminals.

3. The electronic element according to claim 1, wherein the pressing member is provided with a rotating shaft at an end adjacent to the insulating body, the insulating body is correspondingly provided with a rotating slot, and the rotating shaft is received in the rotating slot to achieve the movable connection between the pressing member and the main body.

4. The electronic element according to claim 1, wherein the pressing member is provided with a clamping portion respectively at two sides thereof, the insulating body is correspondingly provided with two clamping slots, and when the pressing member is in the final fixed state, the clamping portions are clamped and fixed in the corresponding clamping slots.

5. The electronic element according to claim 1, wherein each of the terminals mating with the pressing member is provided with a protruding portion at a position adjacent to the soldering portion, and the pressing member presses the terminal through pressing the protruding portion.

6. The electronic element according to claim 5, wherein the protruding portion is formed by bending the terminal.

7. The electronic element according to claim 1, wherein the electronic element is an electrical connector, each of the terminals further comprises a fixing portion fixed to the insulating body and a butting portion extending forwards from the fixing portion, and the soldering portion is located at a rear end of the fixing portion.

8. The electronic element according to claim 7, wherein the insulating body is provided with a tongue plate at a front part, and each of the butting portions is received in the tongue plate and at least partially exposed outside the tongue plate.

9. A method for assembling an electronic element and a circuit board, comprising:
providing an electronic element, wherein the electronic element comprises a main body and a pressing member, the main body comprises an insulating body and multiple terminals fixed to the insulating body, each of the terminals has a soldering portion, the soldering portions are arranged in two rows for being soldered respectively to a top surface and a bottom surface of the circuit board, a distance between the two rows of the soldering portions is greater than or equal to a distance between outermost sides of solder pastes on the top surface and the bottom surface of the circuit board, the pressing member is located at an outer side of one row of the soldering portions and movably connected to the main body, and has an initial open state and a final fixed state, and at this time, the pressing member is in the initial open state;
providing a circuit board, wherein multiple solder pastes are disposed on a top surface and a bottom surface of the circuit board corresponding to the soldering portions;
inserting the circuit board between the two rows of the soldering portions such that a gap exists between the soldering portions and the corresponding solder pastes after insertion;
operating the pressing member to the final fixed state, during which the pressing member presses the corresponding terminals, such that the soldering portions are all contacted with the corresponding solder pastes; and
soldering the soldering portions to the circuit board respectively with the solder pastes by heating.

10. The method according to claim 9, wherein the pressing member comprises a base and a protruding rib extending from the base towards the soldering portions, and the protruding rib forms a pressing portion for pressing the terminals.

11. The method according to claim 9, wherein the pressing member is provided with a rotating shaft at an end adjacent to the insulating body, the insulating body is correspondingly provided with a rotating slot, and the rotating shaft is received in the rotating slot to achieve the movable connection between the pressing member and the main body.

12. The method according to claim 9, wherein the pressing member is provided with a clamping portion respectively at two sides thereof, the insulating body is correspondingly provided with two clamping slots, and when the pressing member is in the final fixed state, the clamping portions are clamped and fixed in the corresponding clamping slots.

13. The method according to claim 9, wherein each of the terminals mating with the pressing member is provided with a protruding portion at a position adjacent to the soldering portion, and the pressing member presses the terminal through pressing the protruding portion.
